(19) United States
(12) Patent Application Publication
(10) Pub. No.: US 2017/0076984 A1
(43) Pub. Date: Mar. 16, 2017

(54) METHOD FOR MANUFACTURING SEMICONDUCTOR DEVICE

(71) Applicant: Kabushiki Kaisha Toshiba, Minato-ku (JP)

(72) Inventor: Hisashi ONODERA, Hanamaki (JP)

(73) Assignee: Kabushiki Kaisha Toshiba, Minato-ku (JP)

(21) Appl. No.: 15/258,643

(22) Filed: Sep. 7, 2016

(30) Foreign Application Priority Data
Sep. 10, 2015 (JP) 2015-178144

(51) Int. Cl. H01L 21/78; H01L 21/027; H01L 21/304

(52) U.S. Cl. CPC H01L 21/78; H01L 21/304; H01L 21/0271

(57) ABSTRACT

Certain embodiments provide a method for manufacturing a semiconductor device including: forming a protection film on a top surface of a semiconductor wafer provided with a plurality of semiconductor elements to cover the plurality of semiconductor elements; removing the protection film of an outer circumferential portion of the semiconductor wafer; grinding at least a part of the outer circumferential portion of the semiconductor wafer exposed by removing the protection film, from the top surface of the semiconductor wafer to a predetermined depth; and polishing an entire surface of a bottom surface of the semiconductor wafer to cause the semiconductor wafer to have a predetermined thickness.

### CROSS REFERENCE TO RELATED APPLICATIONS

This application is based upon and claims the benefit of priority from the prior Japanese Patent Application No. 2015-178144 filed in Japan on Sep. 10, 2015; the entire contents of which are incorporated herein by reference.

### FIELD

Embodiments described herein relate generally to a method for manufacturing a semiconductor device.

### BACKGROUND

In a general method for manufacturing a semiconductor device, a process for polishing an entire surface of a bottom surface of a semiconductor wafer to decrease a thickness of the semiconductor wafer is included. By this process, the thickness of the semiconductor wafer provided with a plurality of semiconductor elements can be changed to a desired thickness. However, a lateral surface of the general semiconductor wafer is curved in a convex shape toward the outside. For this reason, if the entire surface of the bottom surface of the semiconductor wafer is polished, the lateral surface of the polished semiconductor wafer has a pointed shape (edge shape). The edge shape causes the semiconductor wafer to crack and causes handling of the semiconductor wafer to become difficult.

Therefore, to resolve the above problem, a process (edge trimming process) for removing a part of the lateral surface of the semiconductor wafer by grinding is included in a general method for manufacturing a semiconductor device. The lateral surface of the polished semiconductor wafer can be flattened by polishing the semiconductor wafer after executing edge trimming process on the semiconductor wafer.

However, in the edge trimming process according to the related art, a protection film provided on a top surface of the semiconductor wafer and configured using polyimide for example are ground together with the semiconductor wafer. For this reason, the protection film (grinding dust) removed by grinding adheres to a blade used for the grinding. As a result, a grinding failure may occur in the edge trimming process for other semiconductor wafer.

In the related art, the protection film on a dicing line is removed before the edge trimming process. For this reason, a portion where the protection film exists and a portion where the protection film on the dicing line does not exist are mixed on an outer circumferential portion of the semiconductor wafer. Therefore, a reference surface when a position of the semiconductor wafer is measured becomes a top surface of the semiconductor wafer or a top surface of the protection film and a position of the reference surface in a height direction (thickness direction of the semiconductor wafer) varies according to a place. For this reason, wafer alignment performed at the time of the edge trimming process may not be normally performed.

As such, in the related art, it is difficult to execute the edge trimming process with high reliability and high precision. As a result, a yield rate of the semiconductor device decreases.

### BRIEF DESCRIPTION OF THE DRAWINGS

FIG. 1A is a diagram illustrating a method for manufacturing a semiconductor device according to an embodiment and a plan view of a semiconductor wafer when viewed from the upper side;

FIG. 1B is a partial sectional view of the semiconductor wafer along a dashed-dotted line X-X′ in FIG. 1A;

FIG. 2A is a diagram illustrating a method for manufacturing a semiconductor device according to an embodiment and a plan view of a semiconductor wafer when viewed from the upper side;

FIG. 2B is a partial sectional view of the semiconductor wafer along a dashed-dotted line X-X′ in FIG. 2A;

FIG. 3A is a diagram illustrating a method for manufacturing a semiconductor device according to an embodiment and a plan view of a semiconductor wafer when viewed from the upper side;

FIG. 3B is a partial sectional view of the semiconductor wafer along a dashed-dotted line X-X′ in FIG. 3A;

FIG. 4A is a diagram illustrating a modification of a process illustrated in FIG. 3A and a plan view of a semiconductor wafer when viewed from the upper side;

FIG. 4B is a partial sectional view of the semiconductor wafer along a dashed-dotted line X-X′ in FIG. 4A;

FIG. 5A is a diagram illustrating a method for manufacturing a semiconductor device according to an embodiment and a plan view of a semiconductor wafer when viewed from the upper side;

FIG. 5B is a partial sectional view of the semiconductor wafer along a dashed-dotted line X-X′ in FIG. 5A;

FIG. 6A is a diagram illustrating a method for manufacturing a semiconductor device according to an embodiment and a plan view of a semiconductor wafer when viewed from the upper side;

FIG. 6B is a partial sectional view of the semiconductor wafer along a dashed-dotted line X-X′ in FIG. 6A;

FIG. 7A is a diagram illustrating a method for manufacturing a semiconductor device according to an embodiment and a plan view of a semiconductor wafer when viewed from the upper side;

FIG. 7B is a partial sectional view of the semiconductor wafer along a dashed-dotted line X-X′ in FIG. 7A;

FIG. 8A is a diagram illustrating a method for manufacturing a semiconductor device according to an embodiment and a plan view of a semiconductor wafer when viewed from the upper side; and

FIG. 8B is a partial sectional view of the semiconductor wafer along a dashed-dotted line X-X′ in FIG. 8A.

### DETAILED DESCRIPTION

Certain embodiments provide a method for manufacturing a semiconductor device including: forming a protection film on a top surface of a semiconductor wafer provided with a plurality of semiconductor elements to cover the plurality of semiconductor elements; removing the protection film of an outer circumferential portion of the semiconductor wafer; and grinding at least a part of the outer circumferential portion of the semiconductor wafer exposed by removing the protection film, from the top surface of the semiconductor wafer to a predetermined depth.

Hereinafter, a method for manufacturing a semiconductor device according to an embodiment will be described in detail with reference to the drawings.

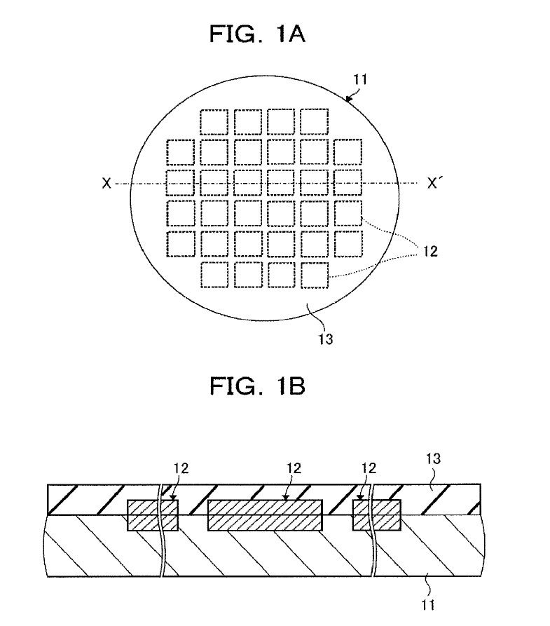

The semiconductor device that is manufactured by the method for manufacturing the semiconductor device according to this embodiment includes a semiconductor substrate, semiconductor elements provided on the semiconductor substrate, and a protection film provided to cover the semiconductor elements. The semiconductor elements are single semiconductor elements such as transistors. However, an integrated circuit (IC) is included in the semiconductor elements in the present application. Hereinafter, the method for manufacturing the semiconductor device will be described in detail with reference to the drawings. FIGS. 1A to 8A described below are diagrams illustrating the method for manufacturing the semiconductor device according to the embodiment and plan views of a semiconductor wafer when viewed from the upper side. FIGS. 1B to 8B are partial sectional views of the semiconductor wafer along a dashed-dotted line X-X′ in FIGS. 1A to 8A.

First, as illustrated in FIGS. 1A and 1B, a plurality of semiconductor elements 12 are formed in a lattice on a top surface of a disk-shaped semiconductor wafer 11 using a general semiconductor process. The semiconductor wafer 11 is configured using silicon, for example. In addition, each semiconductor element 12 includes various impurity layers formed on the top surface of the semiconductor wafer 11 and various electrodes formed on the top surface of the semiconductor wafer 11. When the semiconductor element 12 is a field effect transistor, for example, the various impurity layers are a drain layer, a source layer, and the like and the various electrodes are a drain electrode, a source electrode, a gate electrode, and the like. In addition, when the semiconductor element 12 is a solid-state imaging device, for example, the various impurity layers are a photodiode layer, a charge storage layer, a charge transfer layer, and the like and the various electrodes are a transfer electrode and the like.

As such, after the plurality of semiconductor elements 12 are formed, a photosensitive protection film is formed on an entire surface of the top surface of the semiconductor wafer 11 to cover the plurality of semiconductor elements 12. A desired portion of the protection film 13 can be removed by exposure and development. The protective film 13 is a negative polyimide film, for example. However, the protective film 13 is not limited thereto.

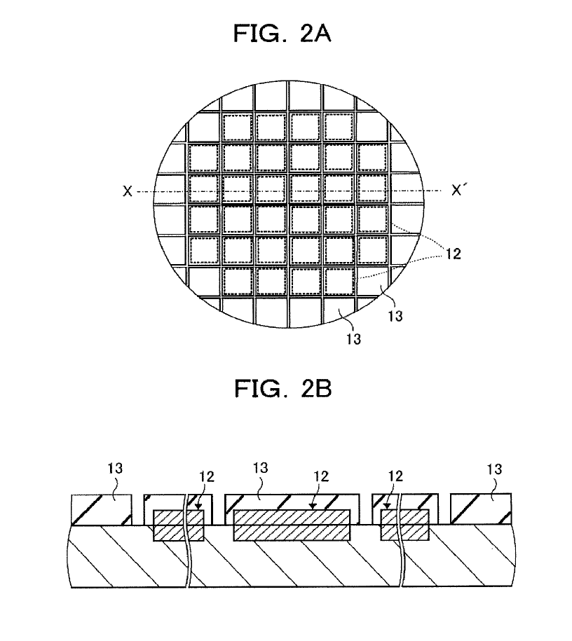

Next, as illustrated in FIGS. 2A and 2B, the protective film 13 on a dicing line including regions between the semiconductor elements 12 is removed by patterning. As a result, the protective film 13 can be suppressed from adhering to a dicing blade used for dicing, in a dicing process for dividing the plurality of semiconductor elements 12 into individual pieces finally.

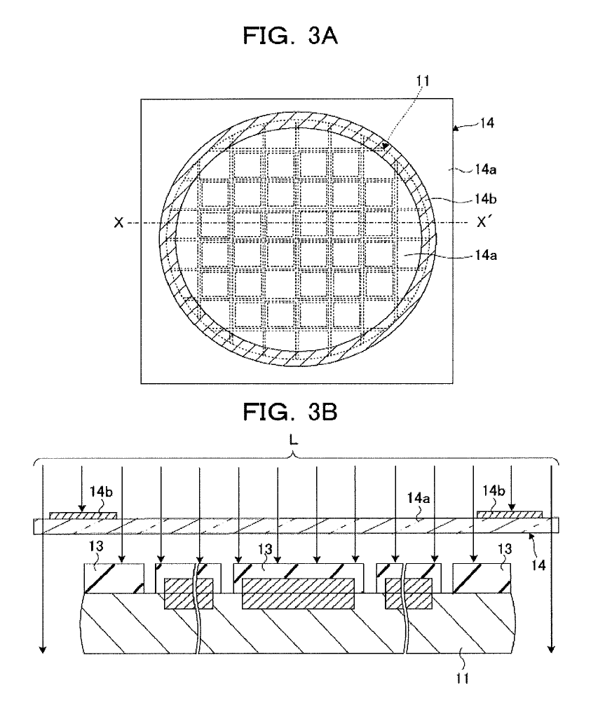

Next, as illustrated in FIGS. 3A and 3B, an exposure mask 14 having a ring-shaped light shielding portion 14b is prepared. The light shielding portion 14b of the exposure mask 14 may be a light shielding film that can shield exposure light. The light shielding portion 14b is a thin film configured using chrome (Cr) , for example. The exposure mask 14 is configured by, for example, providing the light shielding portion 14b on a transparent substrate 14a such as glass plate capable of transmitting the exposure light.

In addition, the exposure mask 14 is disposed on the semiconductor wafer 11, such that the light shielding portion 14b is disposed on an outer circumferential portion of the semiconductor wafer 11. Then, the protection film 13 is exposed using the exposure mask 14. As a result, the protection film 13 (protective film 13 on the outer circumferential portion of the semiconductor wafer 11) existing below the light shielding portion 14b is not exposed and the other protective film 13 is exposed.

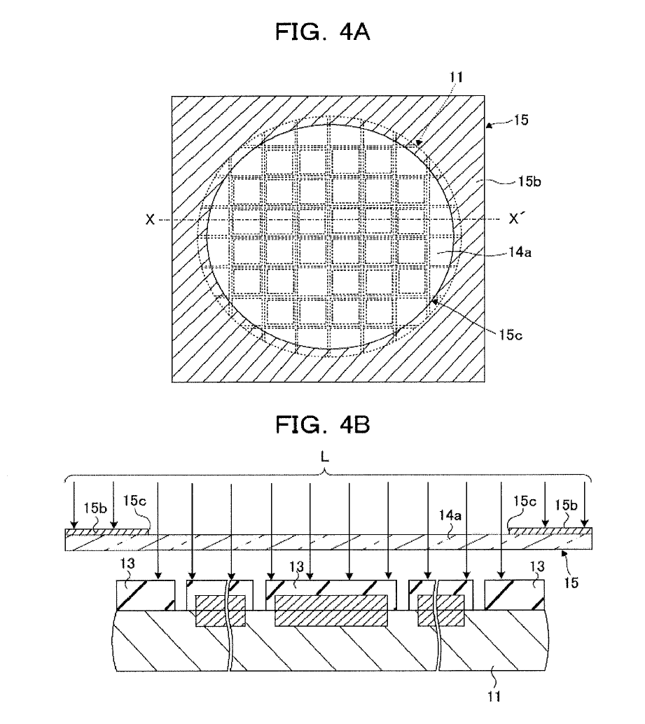

The shape of the light shielding film is not limited to the ring shape of the light shielding portion 14b of the exposure mask 14. As illustrated in FIGS. 4A and 4B illustrating a modification of the exposure mask, a light shielding portion 15b of an exposure mask 15 may be a square light shielding film that has a circular opening 15c. A diameter of the circular opening 15c is smaller than at least a diameter of the semiconductor wafer 11. Even though the exposure mask 15 is used, the protection film on the outer circumferential portion of the semiconductor wafer 11 is not exposed and the other protection film 13 can be exposed.

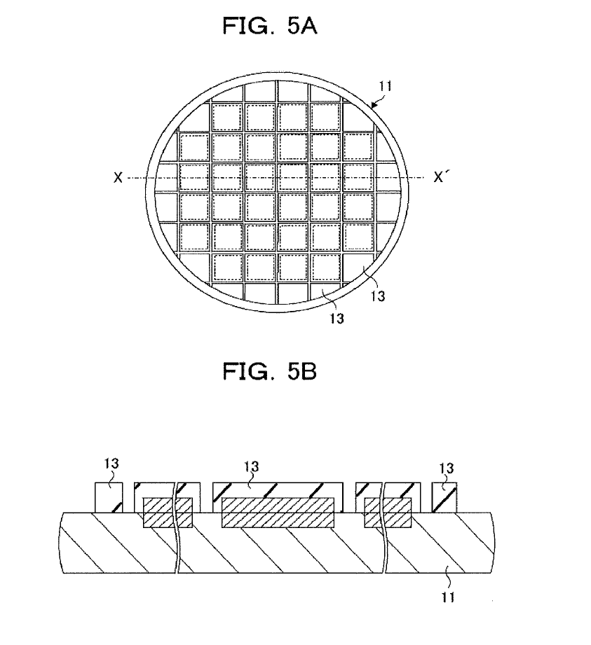

Next, as illustrated in FIGS. 5A and 5B, development processing is executed on the exposed protective film 13, except for a partial region. As a result, the protection film 13 of the outer circumferential portion of the semiconductor wafer 11 is removed and the outer circumferential portion of the semiconductor wafer 11 is exposed. In this embodiment, because the negative polyimide film is used as the protection film 13, only the exposed protection film 13 remains on the semiconductor wafer 11. In addition, the non-exposed protection film on the outer circumferential portion of the semiconductor wafer 11 is removed from the top surface of the semiconductor wafer 11.

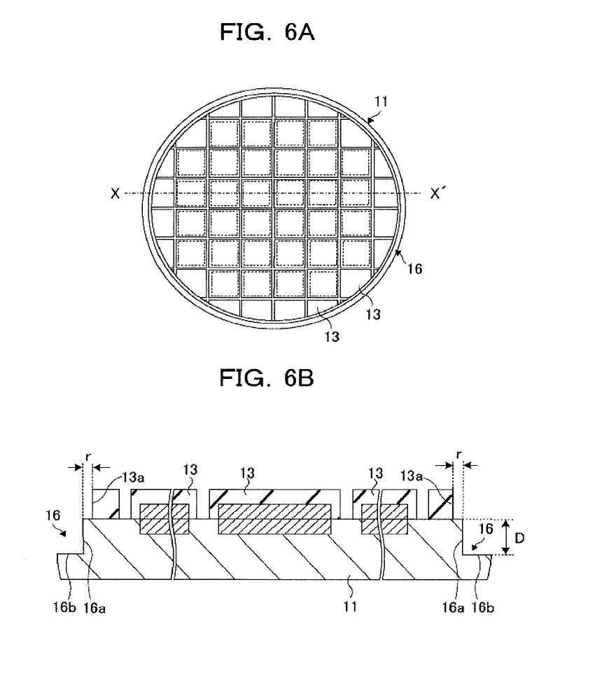

Next, as illustrated in FIGS. 6A and 6B, the semiconductor wafer 11 is aligned such that the semiconductor wafer 11 is disposed at a predetermined position in a grinding device including a blade. In addition, edge trimming process is executed on the outer circumferential portion of the semiconductor wafer 11 exposed by removing the protection film 13. That is, a predetermined region including a lateral surface of the semiconductor wafer 11 in the outer circumferential portion of the semiconductor wafer 11 exposed by removing the protection film 13 is ground from the top surface of the semiconductor wafer 11 to a predetermined depth D and is removed. The grinding is to trim the surface of the semiconductor wafer 11 using the blade. As a result, a dented portion 16 configured using a lateral surface 16a and a bottom surface 16b is formed in a part of the outer circumferential portion of the semiconductor wafer 11. A difference in level is formed between the bottom surface 16b and the top surface of the semiconductor wafer 11.

Because the protection film 13 of the outer circumferential portion of the semiconductor wafer 11 is removed previously, the protection film 13 is not ground when the dented portion 16 is formed. For this reason, grinding dust does not adhere to the blade.

As an example of the blade used for the grinding in the above process, a dicing blade, for example, can be used. The “predetermined depth D” of the dented portion 16 formed by the edge trimming process is equal to or more than a thickness of the semiconductor wafer 11 of which the thickness decreases in the following process. For example, when the thickness of the semiconductor wafer 11 of which the thickness decreases is T, the “predetermined depth D” is equal to or more than T.

The dented portion 16 formed by the grinding may be provided in an entire portion of the outer circumferential portion of the semiconductor wafer 11 exposed by removing the protection film 13. However, the dented portion 16 is preferably provided in a part of the outer circumferential portion of the semiconductor wafer 11. That is, the dented portion 16 is preferably formed such that the lateral surface 16a of the dented portion 16 is disposed at a position moved in an outer circumferential direction of the semiconductor wafer 11 by a predetermined distance r from a position of a lateral surface 13a of an outer circumferential portion of the protection film 13. The dented portion 16 is formed at the position, so that the blade used in the above process can be more surely suppressed from contacting the protection film 13.

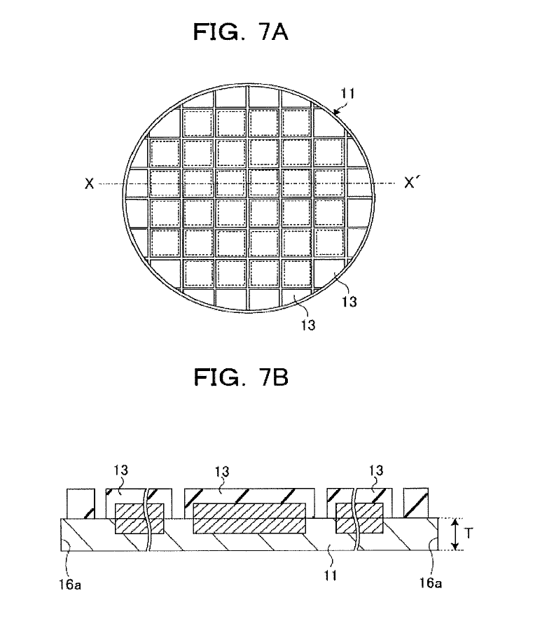

Next, as illustrated in FIGS. 7A and 7B, the semiconductor wafer 11 having the protection film 13 is attached to a protection tap (not illustrated in the drawings) and an entire surface of the bottom surface of the semiconductor wafer 11 is polished until the thickness of the semiconductor wafer 11 becomes the predetermined thickness T. In this way, the thickness of the semiconductor wafer 11 is decreased. Before decreasing the thickness of the semiconductor wafer 11 in the above process, the edge trimming process is executed on the semiconductor wafer 11. For this reason, the lateral surface of the polished semiconductor wafer 11 does not have a pointed shape (edge shape) and has a planar shape to be a shape of the lateral surface 16a of the dented portion 16.

After decreasing the thickness of the semiconductor wafer 11 in the above process, a through-electrode is formed in the semiconductor wafer 11. In addition, a wiring line, an electrode, a protection film, and the like may be formed on the bottom surface of the semiconductor wafer 11 and a semiconductor device 10 including the semiconductor elements 12 may be manufactured. The detailed description and illustration are omitted herein.

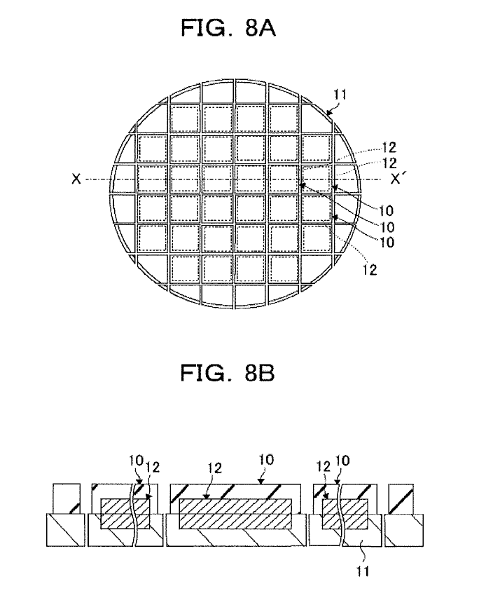

Next, as illustrated in FIGS. 8A and 8B, the semiconductor wafer 11 is cut along the dicing line between the semiconductor elements 12 using, for example, the dicing blade of the grinding device. As a result, the plurality of semiconductor elements 12 are divided into individual pieces and the plurality of semiconductor devices 10 are collectively formed.

According to the method for manufacturing the semiconductor device according to this embodiment described above, the protection film 13 on the outer circumferential portion of the semiconductor wafer 11 is removed before the edge trimming process. Therefore, the grinding dust of the protection film 13 can be suppressed from adhering to the blade in the edge trimming process. As a result, a grinding failure is suppressed from occurring in the edge trimming process for other semiconductor wafer.

In addition, according to the method for manufacturing the semiconductor device according to this embodiment, the protection film 13 on the outer circumferential portion of the semiconductor wafer 11 is removed before the edge trimming process. Therefore, a reference surface when the position of the semiconductor wafer 11 is measured can be standardized with the top surface of the semiconductor wafer 11. For this reason, a position of the reference surface in a height direction (thickness direction of the semiconductor wafer 11) can be suppressed from varying according to a place. As a result, the alignment of the semiconductor wafer 11 performed at the time of the edge trimming process can be performed with high precision.

Therefore, according to the method for manufacturing the semiconductor device according to this embodiment, the edge trimming process can be executed with high reliability and high precision and the semiconductor device 10 can be manufactured with a high yield rate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and sprit of the inventions.

What is claimed is:

1. A method for manufacturing a semiconductor device comprising:
forming a protection film on a top surface of a semiconductor wafer provided with a plurality of semiconductor elements to cover the plurality of semiconductor elements;
removing the protection film of an outer circumferential portion of the semiconductor wafer;
grinding at least a part of the outer circumferential portion of the semiconductor wafer exposed by removing the protection film, from the top surface of the semiconductor wafer to a predetermined depth; and
polishing an entire surface of a bottom surface of the semiconductor wafer to cause the semiconductor wafer to have a predetermined thickness.

2. The method for manufacturing the semiconductor device according to claim 1, wherein
the protection film is a negative polyimide film,
an exposure mask having a light shielding portion is disposed on the semiconductor wafer, such that the light shielding portion is disposed on the outer circumferential portion of the semiconductor wafer,
the protection film is exposed using the exposure mask, and
the exposed protection film is developed to remove the protection film of the outer circumferential portion of the semiconductor wafer.

3. The method for manufacturing the semiconductor device according to claim 2, wherein
the predetermined depth to grind the semiconductor wafer is equal to or more than the predetermined thickness of the semiconductor wafer.

4. The method for manufacturing the semiconductor device according to claim 3, wherein
the protection film on a dicing line of the semiconductor wafer is removed after the protection film is formed, and
the plurality of semiconductor elements are caused to become individual pieces after the semiconductor wafer is caused to have the predetermined thickness.

5. The method for manufacturing the semiconductor device according to claim 2, wherein
the protection film on the dicing line of the semiconductor wafer is removed after the protection film is formed, and
the plurality of semiconductor elements are caused to become individual pieces after the semiconductor wafer is caused to have the predetermined thickness.

6. The method for manufacturing the semiconductor device according to claim 1, wherein
the predetermined depth to grind the semiconductor wafer is equal to or more than the predetermined thickness of the semiconductor wafer.

7. The method for manufacturing the semiconductor device according to claim 6, wherein
the protection film on a dicing line of the semiconductor wafer is removed after the protection film is formed, and
the plurality of semiconductor elements are caused to become individual pieces after the semiconductor wafer is caused to have the predetermined thickness.

8. The method for manufacturing the semiconductor device according to claim 1, wherein
the protection film on a dicing line of the semiconductor wafer is removed after the protection film is formed, and
the plurality of semiconductor elements are caused to become individual pieces after the semiconductor wafer is caused to have the predetermined thickness.

9. The method for manufacturing the semiconductor device according to claim 2, wherein
wherein the light shielding portion is a light shielding curtain.

10. The method for manufacturing the semiconductor device according to claim 2, wherein
wherein the light shielding portion is a light shielding curtain that has a circular opening having a diameter smaller than a diameter of the semiconductor wafer.

11. The method for manufacturing the semiconductor device according to claim 2, wherein
the light shielding portion is configured using chrome.

12. The method for manufacturing the semiconductor device according to claim 2, wherein
the exposure mask is configured using a transparent substrate transmitting exposure light and the light shielding portion provided on the transparent substrate.
